(19) United States
(12) Patent Application Publication
(10) Pub. No.: US 2026/0196425 A1
(43) Pub. Date: Jul. 9, 2026

(54) CIRCUIT BREAKER TRIP DEVICE AND MOLDED CASE CIRCUIT BREAKER INCLUDING THE SAME

(71) Applicant: HD HYUNDAI ELECTRIC CO., LTD., Seongnam-si (KR)

(72) Inventor: Byung Soo AN, Seoul (KR)

(73) Assignee: HD HYUNDAI ELECTRIC CO., LTD., Seongnam-si (KR)

(21) Appl. No.: 19/262,127

(22) Filed: Jul. 8, 2025

(30) Foreign Application Priority Data
Jan. 6, 2025 (KR) 10-2025-0001803

(51) Int. Cl. H01H 21/22; H01H 50/44; H01H 71/02; H05K 7/14

(52) U.S. Cl. CPC H01H 21/22; H01H 50/44; H01H 71/02; H05K 7/1427

(57) ABSTRACT

Proposed is a circuit breaker trip device and a molded case circuit breaker including the same, capable of being miniaturized by eliminating a dependent movement stroke of a trip lever with respect to a backlash of a circuit breaker handle and by reducing the operating radius and number of parts. The circuit breaker trip device includes a trip shooter for moving by a reset operation of a circuit breaker handle, and a trip lever interlocked with the trip shooter for moving to a reset position, wherein the trip shooter additionally moves by a predetermined length even after the trip lever stops at the reset position.

### CROSS REFERENCE TO RELATED APPLICATION

This application claims priority to Korean Patent Application No. 10-2025-0001803 (filed on Jan. 6, 2025), which is hereby incorporated by reference in its entirety.

### BACKGROUND

The present disclosure relates to a circuit breaker trip device and a molded case circuit breaker including the same and, more specifically, to a circuit breaker trip device and a molded case circuit breaker including the same, capable of being miniaturized by eliminating a dependent movement stroke of a trip lever with respect to a backlash of a circuit breaker handle and by reducing the operating radius and number of parts.

A circuit breaker, especially a molded case circuit breaker, is a device that protects electrical equipment and ensures user safety by quickly interrupting a circuit when an abnormal condition such as overcurrent, short circuit, or undervoltage occurs in an electrical circuit.

The molded case circuit breaker is widely used in residential, commercial and industrial environments and is required to exhibit high reliability and fast operation. Such a molded case circuit breaker generally includes various components such as a mechanism, a trip device, a contact point unit, an insulating unit, and an enclosure, and various technical designs are applied to detect current flow and safely interrupt the same.

Conventional molded case circuit breakers provide basic protection functions as described above, but there are various technical limitations.

In the case of the trip device, a backlash occurs due to interference between handle operation and trip operation, which can result in unstable trip operation and malfunction. In addition, there are problems in that it is difficult to be miniaturized, and productivity and efficiency are reduced because of the design complexity of the trip device.

Meanwhile, a toggle-type current-limiting device of the molded case circuit breaker requires sufficient contact parting distance and fast contact parting speed in order to quickly extinguish the high temperature and high pressure arc that occurs in the event of a short circuit. However, this is not be stably implemented in the conventional technology, such that the arc extinction time is prolonged and there is a possibility of interruption failure. Further, there is a limitation that the safety is reduced in a high-voltage environment due to the occurrence of torsion problems in components such as toggle links or insufficient insulation performance.

In addition, there is a problem in the returning process of the movable electrode after the breaking operation. Specifically, when the movable electrode returns after a short circuit event, there is a possibility of exceeding the operating limit of the mechanism due to excessive return load or causing re-ignition due to return instability. Also, it is difficult to control the return load and speed, such that the reliability and performance of the circuit breaker are degraded, and there is also a risk of malfunction due to an external impact.

In order to overcome these limitations of such conventional technology, there is a growing need for a new molded case circuit breaker having all of the stability and miniaturization of trip devices, the enhanced insulation performance and improved assembly of the toggle-type current-limiting device, and the return load control and stability of a return structure.

### SUMMARY

Exemplary embodiments of the present disclosure are intended to prevent malfunction of trip operations and optimize the design of internal parts of a trip device by effectively absorbing a backlash generated during handle manipulation.

In addition, it is intended to house a PCB module of a coil assembly within a trip device, by replacing the rotational motion and coil spring structure of the existing trip device with a linear motion and compression spring application structure and by minimizing the volume required for implementing operations.

In addition, it is intended to provide a miniaturized design applicable to circuit breakers of various structures by reducing the size of the trip device, and to enhance both productivity and maintenance efficiency by improving the assembly of the trip device.

In addition, it is intended to enhance the operation speed so that the arc can be quickly extinguished in the event of a short circuit by improving insulation performance and assembly of the toggle-type current-limiting device, and to ensure reliability to be applied to high voltage environments by optimizing the insulation structure of a crossbar and a crossbar cap.

In addition, it is intended to solve the torsion problem of the toggle link applicable to the crossbar assembly and to eliminate the instability during assembly through an integrated structure.

In addition, it is intended to shorten the arc extinction time and increase the success rate of interruption in the event of a short circuit by optimizing the contact parting distance and speed.

In addition, it is intended to improve the stability and reliability of the return operation after the event of a short circuit by improving the return structure of the toggle-type current-limiting mechanism.

In addition, it is intended to allow the movable electrode to stably return to the initial position and to prevent re-ignition caused by an external impact by introducing a spring structure capable of carefully controlling the return load and by minimizing excessive load generated during the return process.

According to one aspect of the present disclosure, there is provided a circuit breaker trip device including a trip shooter for moving by a reset operation of a circuit breaker handle, and a trip lever interlocked with the trip shooter for moving to a reset position, wherein the trip shooter additionally moves by a predetermined length even after the trip lever stops at the reset position.

The circuit breaker trip device according to the present disclosure may further include a frame forming an outer shape of the trip device and to which the trip lever is slidably coupled.

The trip shooter may be slidably coupled between the trip lever and the frame.

The circuit breaker trip device according to the present disclosure may further include a trip shooter spring for connecting the frame and the trip shooter, and a trip lever spring for connecting the trip shooter and the trip lever.

The circuit breaker trip device according to the present disclosure may further include a coil assembly provided inside the frame for generating an electromagnetic force in response to an external voltage, and a motion core configured to be fixed by a magnet provided inside the coil assembly or to move away from the magnet by the electromagnetic force.

The circuit breaker trip device according to the present disclosure may further include a lever holder, one side of which is connected to the motion core and rotates according to a movement of the motion core.

The lever holder may serve as a latch for restricting the trip lever to be fixed at the reset position or releasing the same.

The circuit breaker trip device according to the present disclosure may further include a lever holder pin forming a rotation shaft of the lever holder.

The circuit breaker trip device according to the present disclosure may further include a frame cover configured to be coupled to one side of the frame.

The circuit breaker trip device according to the present disclosure may further include a lever holder pin separation preventing unit formed to extend by a predetermined length from the frame cover toward the frame for preventing the lever holder pin from being detached.

The circuit breaker trip device according to the present disclosure may further include a trip lever separation preventing unit formed to extend by a predetermined length from the frame cover toward the frame for preventing the trip lever from being detached.

The trip lever may include at least one guiding groove unit for preventing a detachment of the trip lever assembled to the frame and for forming a path where the trip lever moves.

The frame may include at least one stopper interlocked with the guiding groove unit for guiding a movement of the trip lever and for stopping the trip lever from moving further after moving to the reset position.

The circuit breaker trip device according to the present disclosure may further include a printed circuit board (PCB) unit electrically connected to the coil assembly for receiving an external voltage signal and supplying a voltage to the coil assembly, wherein the PCB unit is housed inside the frame.

The trip device may be a shunt trip (SHT) or an under voltage trip (UVT).

According to another aspect of the present disclosure, there is provided a molded case circuit breaker including a terminal unit for inputting and outputting current, a fixed electrode electrically connected to the terminal unit, a movable electrode electrically connected to or disconnected from the fixed electrode in order to interrupt or establish a current flow, a mechanism for opening and closing an electrical connection to the fixed electrode by moving the movable electrode, a handle connected to the mechanism to be manually operable, and a trip device for operating the mechanism when a voltage drops or according to an external voltage signal, wherein the trip device comprises a trip shooter for linearly moving in response to a reset operation of the handle and a trip lever interlocked with the trip shooter for linearly moving to a reset position.

The trip shooter may additionally move by a predetermined length even after the trip lever stops at the reset position.

The trip device may further include a frame forming an outer shape of the trip device and to which the trip lever is slidably coupled and the trip shooter is slidably coupled between the trip lever and the frame.

The trip device may further include a coil assembly provided inside the frame for generating an electromagnetic force in response to an external voltage, a motion core configured to be fixed by a magnet provided inside the coil assembly or to move away from the magnet by the electromagnetic force, and a lever holder, one side of which is connected to the motion core and rotates according to a movement of the motion core.

The trip device may further include a printed circuit board (PCB) unit electrically connected to the coil assembly for receiving an external voltage signal and supplying a voltage to the coil assembly, wherein the PCB unit is housed inside the frame.

Exemplary embodiments of the present disclosure are intended to prevent malfunction of trip operations and optimize the design of internal parts of a trip device by effectively absorbing a backlash generated during handle manipulation.

In addition, it is intended to house a PCB module of a coil assembly within a trip device, by replacing the rotational motion and coil spring structure of the existing trip device with a linear motion and compression spring application structure and by minimizing the volume required for implementing operations.

In addition, it is intended to provide a miniaturized design applicable to circuit breakers of various structures by reducing the size of the trip device, and to enhance both productivity and maintenance efficiency by improving the assembly of the trip device.

In addition, it is intended to enhance the operation speed so that the arc can be quickly extinguished in the event of a short circuit by improving insulation performance and assembly of the toggle-type current-limiting device, and to ensure reliability to be applied to high voltage environments by optimizing the insulation structure of a crossbar and a crossbar cap.

In addition, it is intended to solve the torsion problem of the toggle link applicable to the crossbar assembly and to eliminate the instability during assembly through an integrated structure.

In addition, it is intended to shorten the arc extinction time and increase the success rate of interruption in the event of a short circuit by optimizing the contact parting distance and speed.

In addition, it is intended to improve the stability and reliability of the return operation after the event of a short circuit by improving the return structure of the toggle-type current-limiting mechanism.

In addition, it is intended to allow the movable electrode to stably return to the initial position and to prevent re-ignition caused by an external impact by introducing a spring structure capable of carefully controlling the return load and by minimizing excessive load generated during the return process.

### BRIEF DESCRIPTION OF THE DRAWINGS

FIG. 1 is a perspective view showing a molded case circuit breaker according to an exemplary embodiment of the present disclosure.

FIG. 2 is an internal side view showing a molded case circuit breaker according to an exemplary embodiment of the present disclosure.

FIG. 3 is a perspective view showing a state where a trip device is separated from a molded case circuit breaker according to an exemplary embodiment of the present disclosure.

FIG. 4 is a perspective view showing a circuit breaker trip device according to an exemplary embodiment of the present disclosure.

FIG. 5 is an exploded perspective view showing a circuit breaker trip device according to an exemplary embodiment of the present disclosure.

FIG. 6 is a perspective view showing a trip shooter of a circuit breaker trip device according to an exemplary embodiment of the present disclosure.

FIGS. 7A and 7B are a perspective view showing a trip lever of a circuit breaker trip device according to an exemplary embodiment of the present disclosure.

FIGS. 8A and 8B are a perspective view showing a frame of a circuit breaker trip device according to an exemplary embodiment of the present disclosure.

FIG. 9 is a perspective view showing a lever holder of a circuit breaker trip device according to an exemplary embodiment of the present disclosure.

FIG. 10 is a perspective view showing a frame cover of a circuit breaker trip device according to an exemplary embodiment of the present disclosure.

FIG. 11 is a perspective view showing a circuit breaker trip device according to an exemplary embodiment of the present disclosure.

FIGS. 12A, 12B, 13A, and 13B are a side view and a rear view sequentially showing a reset process of a circuit breaker trip device according to an exemplary embodiment of the present disclosure.

FIGS. 14A and 14B are a side view and a rear view sequentially showing a trip process of a circuit breaker trip device according to an exemplary embodiment of the present disclosure.

FIG. 15 is a perspective view showing a single-pole breaking unit of a molded case circuit breaker according to an exemplary embodiment of the present disclosure.

FIG. 16 is an internal side view showing a single-pole breaking unit of a molded case circuit breaker according to an exemplary embodiment of the present disclosure.

FIG. 17 is a side perspective view showing a contact base of a single-pole breaking unit of a molded case circuit breaker according to an exemplary embodiment of the present disclosure.

FIG. 18 is a perspective view showing a crossbar assembly according to an exemplary embodiment of the present disclosure.

FIG. 19 is an exploded perspective view showing a crossbar assembly according to an exemplary embodiment of the present disclosure.

FIG. 20 is a perspective view showing a crossbar according to an exemplary embodiment of the present disclosure.

FIG. 21 is a perspective view showing a crossbar when viewed from another side according to an exemplary embodiment of the present disclosure.

FIG. 22 is a perspective view showing a crossbar cap according to an exemplary embodiment of the present disclosure.

FIG. 23 is a perspective view showing a crossbar cap when viewed from another side according to an exemplary embodiment of the present disclosure.

FIG. 24 is an exploded perspective view showing an assembly structure of a movable electrode and a toggle link according to an exemplary embodiment of the present disclosure.

FIG. 25 is a perspective view showing an integrated structure of a toggle link according to an exemplary embodiment of the present disclosure.

FIG. 26 is a conceptual diagram showing that a crossbar assembly according to an exemplary embodiment of the present disclosure has an increased insulation distance compared to the conventional one.

FIG. 27 is a perspective view showing a case where a toggle link spring is applied to a movable electrode and a toggle link according to an exemplary embodiment of the present disclosure.

FIG. 28 is a perspective view showing a toggle link spring according to an exemplary embodiment of the present disclosure.

FIGS. 29A, 29B, 29C, 29D, and 29E are a side view sequentially showing a contact parting process of a movable electrode in a crossbar assembly according to an exemplary embodiment of the present disclosure.

### DETAILED DESCRIPTION

Hereinafter, preferred exemplary embodiments of the present disclosure will be described in detail with reference to the accompanying drawings. However, the present disclosure may not be limited to the exemplary embodiments described herein and may be embodied in various other forms. Rather, the exemplary embodiments introduced herein may be provided so that the disclosed contents can be thorough and complete and so that the spirit of the present disclosure can be sufficiently conveyed to those skilled in the art. Throughout the specification, the same reference numerals may represent the same components.

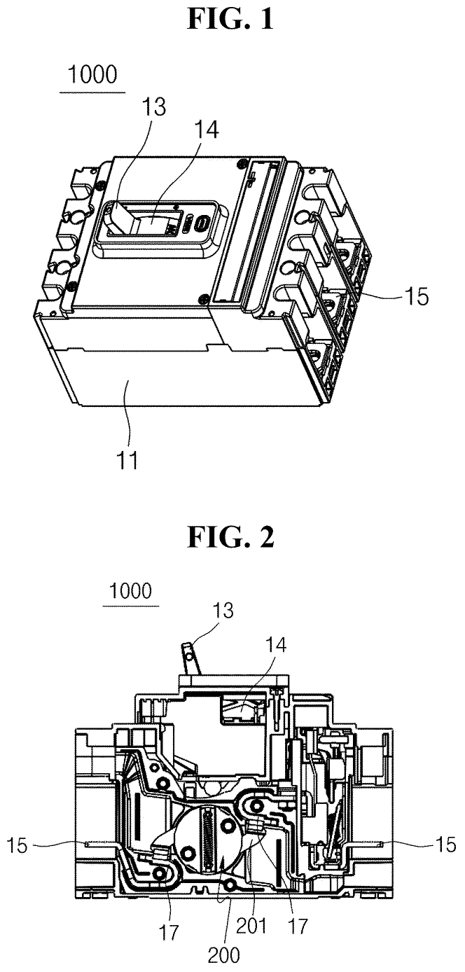

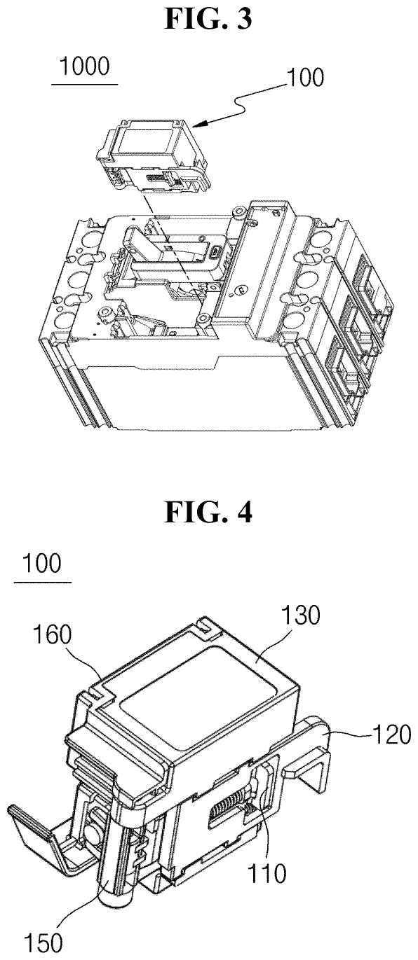

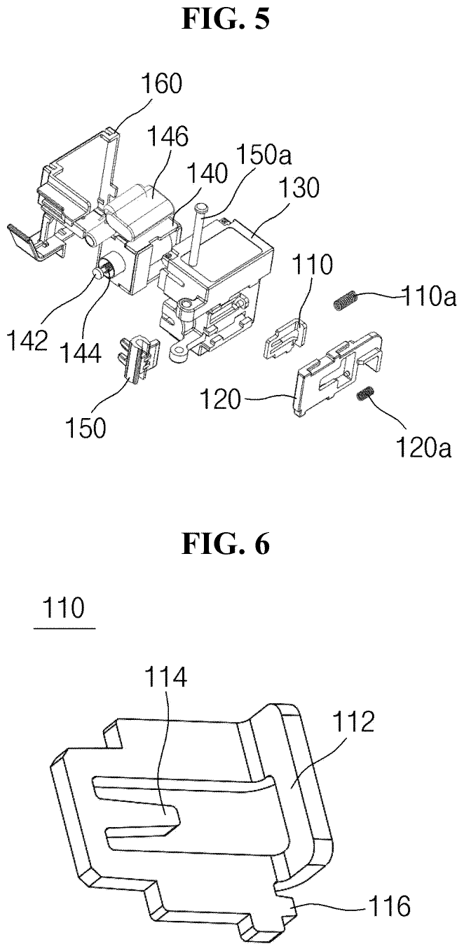

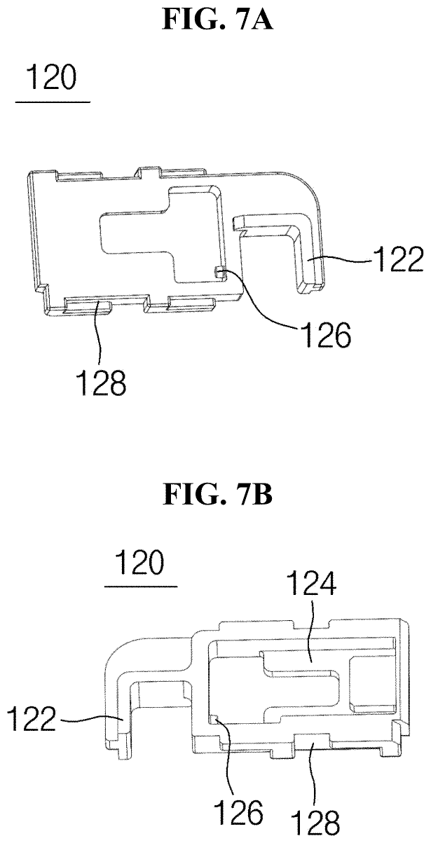

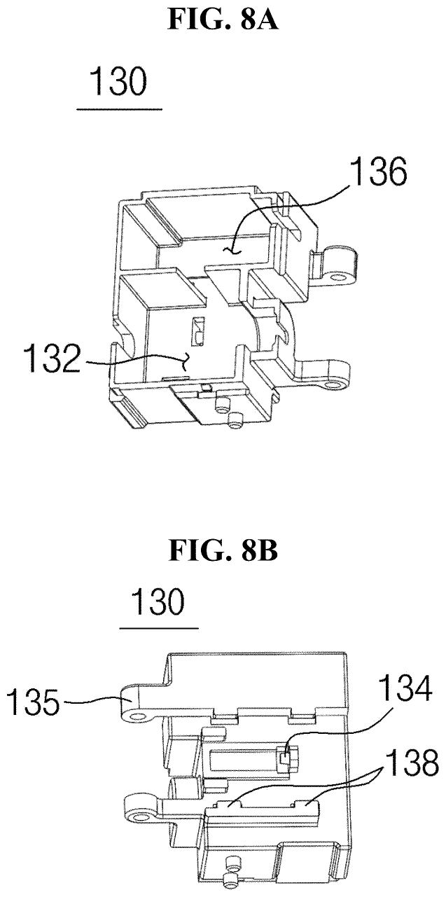

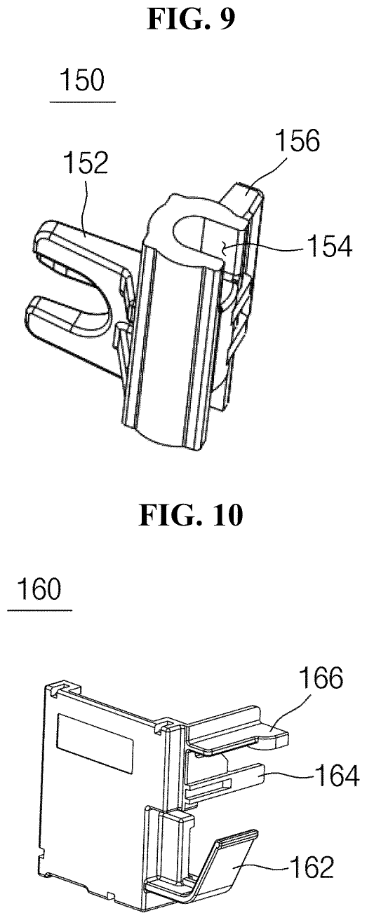

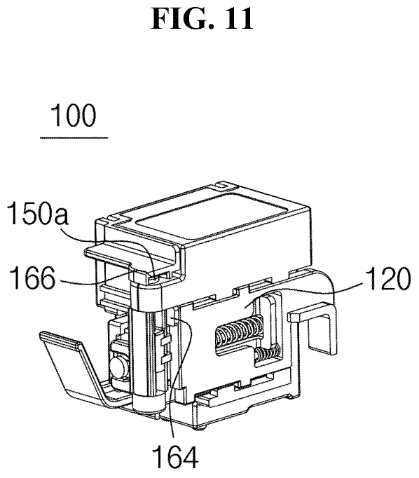

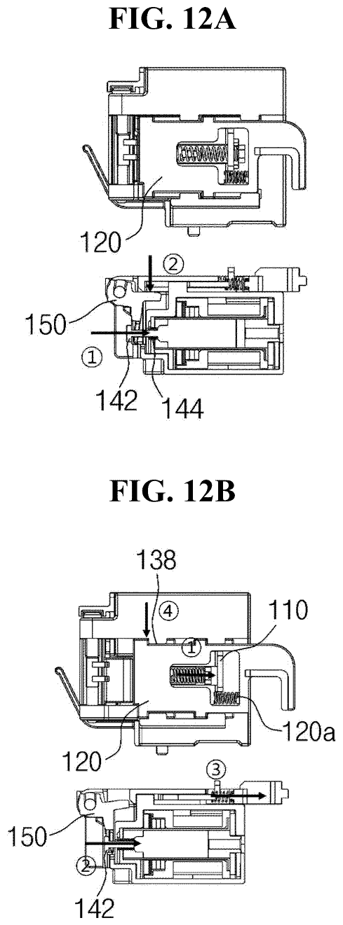

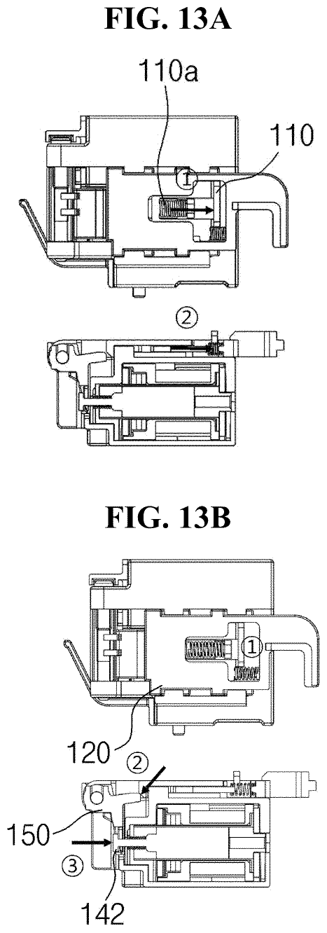

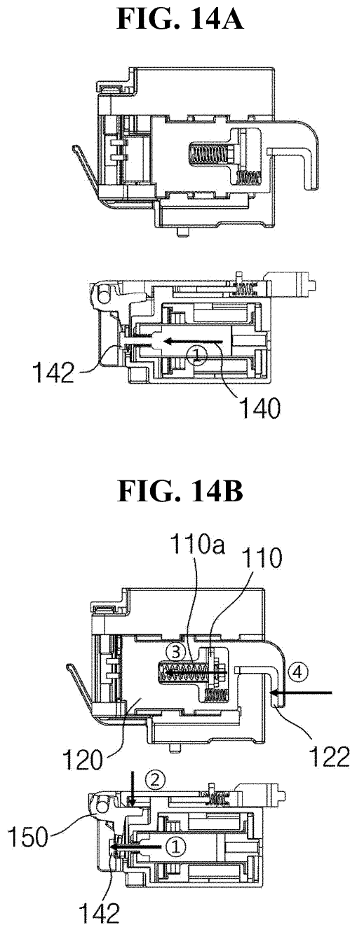

FIG. 1 is a perspective view showing a molded case circuit breaker according to an exemplary embodiment of the present disclosure, FIG. 2 is an internal side view showing a molded case circuit breaker according to an exemplary embodiment of the present disclosure, and FIG. 3 is a perspective view showing a state where a trip device is separated from a molded case circuit breaker according to an exemplary embodiment of the present disclosure. FIG. 4 is a perspective view showing a circuit breaker trip device according to an exemplary embodiment of the present disclosure, FIG. 5 is an exploded perspective view showing a circuit breaker trip device according to an exemplary embodiment of the present disclosure, and FIG. 6 is a perspective view showing a trip shooter of a circuit breaker trip device according to an exemplary embodiment of the present disclosure. FIGS. 7A and 7B are a perspective view showing a trip lever of a circuit breaker trip device according to an exemplary embodiment of the present disclosure, FIGS. 8A and 8B are a perspective view showing a frame of a circuit breaker trip device according to an exemplary embodiment of the present disclosure, and FIG. 9 is a perspective view showing a lever holder of a circuit breaker trip device according to an exemplary embodiment of the present disclosure. FIG. 10 is a perspective view showing a frame cover of a circuit breaker trip device according to an exemplary embodiment of the present disclosure, FIG. 11 is a perspective view showing a circuit breaker trip device according to an exemplary embodiment of the present disclosure, and FIGS. 12 and 13 are a side view and a rear view sequentially showing a reset process of a circuit breaker trip device according to an exemplary embodiment of the present disclosure. FIGS. 14A and 14B are a side view and a rear view sequentially showing a trip process of a circuit breaker trip device according to an exemplary embodiment of the present disclosure.

Referring to FIGS. 1 to 14, a circuit breaker trip device 100 according to an exemplary embodiment of the present disclosure may largely include a trip shooter 110 moving in response to a reset operation of a circuit breaker handle 13 and a trip lever 120 interlocked with the trip shooter 110 for moving to a reset position.

Such a trip device 100 may be installed to perform a trip operation for interrupting the circuit breaker. The trip device 100 of the present disclosure may be applied to various types of circuit breakers, but the present exemplary embodiment may be described mainly with reference to a molded case circuit breaker 1000.

The molded case circuit breaker 1000 to which the present disclosure is applied may include an enclosure 11 forming an outer shape as shown in FIGS. 1 and 2. The enclosure 11 may serve to house all internal components of the molded case circuit breaker 1000 and protect the same from external impact and environmental factors.

The enclosure 11 may be manufactured from a material with excellent durability and insulation and may particularly designed to maintain a sufficient insulation distance from internal components where high voltage is generated. In addition, the enclosure 11 may function to stably secure the positions of internal components and absorb vibrations or impacts that may occur during operation.

A handle 13 may be provided on a front surface of the enclosure 11. The handle 13 may be a main component for manually manipulating the molded case circuit breaker 1000, which is connected to a mechanism 14 to be described later to control an opening and closing state of the molded case circuit breaker 1000. That is, the molded case circuit breaker 1000 may be manually manipulated to an ON, OFF, or RESET state through the handle 13, and a display unit (not shown) for visually indicating the state of the molded case circuit breaker 1000 may be designed into an integrated structure.

The mechanism 14 may be a device for implementing a core operation of the molded case circuit breaker 1000, which transmits the power transmitted from the handle 13 and the trip device 100 to a movable electrode 201 to open and close the electrical connection with a fixed electrode 17. The mechanism 14 may be operated through a manual manipulation of the handle 13 or an automatic operation of the trip device 100, thereby ensuring a rapid and accurate operation of the molded case circuit breaker 1000. Such a mechanism 14 may include a spring and a link structure designed to absorb an excessive load generated during an operation and to assist with a return operation.

A terminal unit 15 may be provided on both sides of the enclosure 11. The terminal unit 15 may provide an input and output path for current and may be a point connected to an external circuit. The terminal unit 15 may be manufactured from a material with a low-resistance and high-durability in order to stably transmit high currents, and may be electrically connected to the fixed electrode 17.

The fixed electrode 17 and the movable electrode 201 may be configured to control the flow of current, wherein the fixed electrode 17 is integrated with the terminal unit 15 to maintain a fixed state, and the movable electrode 201 is in contact with or separated from the fixed electrode 17 according to the operation of the mechanism 14. The movable electrode 201 may be configured to rapidly do the contact parting in response to a fault current for interrupting the current and to reliably return through a spring or a link structure after tripping.

Also, there may be provided a crossbar assembly 200 for rotatably supporting the movable electrode 201. A detailed configuration of the crossbar assembly 200 will be described later.

Meanwhile, the trip device 100 according to an exemplary embodiment of the present disclosure may be installed inside the molded case circuit breaker 1000 as shown in FIG. 3. Herein, the trip device 100 may be a shunt trip (SHT) or an under voltage trip (UVT).

The shunt trip (SHT) may be a device for remotely operating the circuit breaker by receiving an external voltage signal. The SHT may include a coil assembly 140 to be described later, and when a voltage signal is applied from an external control device, an electromagnetic force may be generated in the coil. The electromagnetic force may operate a motion core (MOV core) 142 to turn the circuit breaker into a trip state. The SHT may be mainly used to remotely shut off power in an emergency or to operate the circuit breaker in an automated system. In addition, The SHT may provide a remote control function in industrial equipment or building management systems, thereby enhancing equipment management efficiency.

The UVT may be a device for automatically operating the circuit breaker by detecting a voltage drop. The UVT may operate the trip mechanism by means of the elastic force of an internal spring when the magnetic force of the coil is reduced or released as the voltage falls less than or equal to a predetermined threshold. The UVT may be mainly used to ensure the stability of the power supply system and may prevent electrical facilities or equipment from being damaged under low voltage conditions. By automatically tripping the circuit breaker when power is supplied less than or equal to the set voltage, the UVT may reduce the risk of equipment overload and damage and may maintain a stable power supply environment.

In general, the SHT and the UVT may have similar structures, and in the exemplary embodiment of the present disclosure, a case where the trip device 100 is configured as the SHT will be described as an example.

As described above, the trip device 100 according to an exemplary embodiment of the present disclosure may include a trip shooter 110 moving in response to the reset operation of the circuit breaker handle 13 and a trip lever 120 interlocked with the trip shooter 110 for moving to the reset position.

In addition, there is a frame 130 forming the outer shape of the trip device 100, and the trip lever 12 may be slidably coupled to the side surface of the frame 130, and the trip shooter 110 may be slidably coupled between the trip lever 120 and the frame 130.

In addition, there are provided a trip shooter spring 110a for connecting the frame 130 and the trip shooter 110 and a trip lever spring 120a for connecting the trip shooter 110 and the trip lever 120.

Specifically, the trip shooter 110 may be a component associated with the manipulation of the handle 13, and may be disposed to be slidable inside between the trip lever 120 and the frame 130 in a straight direction. The trip shooter 110 may have a linear motion structure designed to absorb a backlash generated by the manipulation of the handle 13, and may be connected to the frame 130 via the trip shooter spring 110a, and may be connected to the trip lever 120 via the trip lever spring 120a.

As shown in FIG. 6, a handle contact unit 112 may be provided on one side of the trip shooter 110 so as to be moved by the manipulation of the handle 13. Also, a first trip shooter spring assembling unit 114 to which the trip shooter spring 110a is connected may be provided in the center. A first trip lever spring assembling unit 116 to which the trip lever spring 120a is connected may be protrudingly formed at the lower portion of the handle contact unit 112.

Meanwhile, as shown in FIGS. 4 and 5, because being connected to the trip shooter 110 by the trip lever spring 120a, the trip lever 120 may also linearly move in conjunction therewith when the trip shooter 110 linearly moves to the reset position by the manipulation of the handle 13.

One side of the trip lever spring 120a may be connected to the first trip lever spring assembling unit 116 formed in the trip shooter 110, and the other side thereof may be connected to the second trip lever spring assembling unit 126 formed in the trip lever 120. The shape and position of the second trip lever spring assembling unit 126 may be illustrated in FIGS. 7A and 7B.

The trip lever 120 may be slidably coupled to the side surface of the frame 130. To this end, the trip lever 120 may include at least one guiding groove unit 128 for preventing the trip lever 120 assembled with the frame 130 from being detached and for forming a path through which the trip lever 120 moves.

In response to this, the frame 130 may include at least one stopper 138 interlocked with the guiding groove unit 128 for serving to guide the movement of the trip lever 120 and to stop the trip lever 120 from moving further after moving to the reset position.

In the present exemplary embodiment, as shown in FIGS. 7 and 8, two guiding groove units 128 may be provided on the lower portion of the trip lever 120 and two on the upper portion thereof, respectively, and correspondingly, two stoppers 138 may be provided on the lower portion of one side surface of the frame 130 and two at the upper portion thereof.

Accordingly, when the stopper 138 moves along the guiding groove unit 128, the trip lever 120 may move in a straight line along the side surface of the frame 130, and when the stopper 138 is caught on the end portion of the guiding groove unit 128 and stops, the trip lever 120 may stop at the reset position.

As previously described, even when the trip lever 120 stops, the trip shooter 110 may further move by a predetermined distance to absorb the backlash generated by the manipulation of the handle 13.

The trip lever 120 may be provided with a trip shooter housing unit 124 where the trip shooter 110 is mounted on a side surface facing the frame 130. As shown in FIG. 7B, the trip shooter housing unit 124 may form a space where the trip shooter 110 can slide between the trip lever 120 and the frame 130.

A mechanism striking unit 122 may be provided at one end portion of the trip lever 120. The mechanism striking unit 122 may strike the mechanism 14 during the trip operation of the trip lever 120, thereby performing the circuit breaking operation.

The frame 130 may form a certain space inside, wherein a PCB housing unit 136 where a printed circuit board (PCB, 146) is housed is formed at an upper portion, and a coil assembly housing unit 132 where a coil assembly 140 is housed is formed at a lower portion as shown in FIG. 8A.

Meanwhile, the coil assembly 140 may receive an external voltage signal to generate a magnetic field, which operates the motion core 142. The coil assembly 140 may be installed in the coil assembly housing unit 132 on the inside of the frame.

When an external voltage is applied to the coil assembly 140, a strong magnetic field may be formed, which serves as a driving force to release or move the motion core 142 from the binding force of the magnet (not shown).

The PCB unit 146 may be a component for controlling the operation of the coil assembly 140 and the motion core 142 and for processing an external signal. As described above, the PCB unit 146 may be mounted on the PCB housing unit 136 inside the frame 130.

In the conventional work, the PCB unit 146 may be provided separately outside the trip device 100 rather than inside the frame 130 because the rotational motion and the coil spring structure in the operation of the trip device 100 take up a large amount of space. However, in the present disclosure, the PCB unit 146 may be housed inside the frame 130 of the trip device 100 by replacing the main operating components, such as the trip shooter 110 and the trip lever 120, with a linear motion and a compression spring application structure to minimize the volume required for implementing operations.

The motion core 142 may be provided to be movable inside the coil assembly 140. The motion core 142 may be fixed at the reset position by the binding force of the magnet, but may move by the electromagnetic force generated in the coil assembly 140, thereby starting the trip operation. A motion core spring 144 may be coupled to one side of the motion core 142 to provide a restoring force when the motion core 142 moves.

The motion core 142 may be connected to the lever holder 150, and the lever holder 150 may be configured to rotate according to the movement of the motion core 142. The motion core catching unit 152 of the lever holder 150 may be connected to one end of the motion core 142.

Also, as shown in FIGS. 5 and 8, the lever holder 150 may be assembled with one side of the frame 130 by inserting the lever holder pin 150a in a state where a pin inserting unit 154 of the lever holder 150 is coupled to a lever holder assembling unit 135 formed in the frame 130. The lever holder pin 150a may form a rotation shaft on which the lever holder 150 rotates. The lever holder 150 may include a trip lever catching unit 156 and may serve as a latch for restricting the trip lever 120 to be fixed at the reset position according to the rotational position of the trip lever catching unit 156 or for releasing the same therefrom.

Meanwhile, a frame cover 160 may be coupled to one side of the frame 130. As shown in FIG. 10, the frame cover 160 may be formed to extend by a predetermined length toward the frame 130 and may include a lever holder pin separation preventing unit 166 for preventing the lever holder pin 150a from being detached. Also, the frame cover 160 may be formed to extend by a predetermined length toward the frame 130 and may include a trip lever separation preventing unit 164 for preventing the trip lever 120 from being detached.

As shown in FIG. 11, the lever holder pin separation preventing unit 166 may cover the upper portion of the lever holder pin 150a to prevent the lever holder pin 150a from coming out, and the trip lever separation preventing unit 164 may also serve to prevent the trip lever 120 from sliding out from the frame 130.

Also, a mounting shape unit 162 may be provided on the lower portion of the frame cover 160 such that the trip device 100 can be stably mounted inside the molded case circuit breaker 1000.

Hereinafter, an operation process of the trip device 100 configured as such will be described with reference to FIGS. 12 to 14.

First, to explain the reset operation process, as shown in FIG. 12A, the restoring force of the motion core spring 144 may act at first in the direction of the arrow, so that the motion core 142 is in a state of receiving the load in that direction. Also, \textcircled{2} the lever holder 150 may be in a fixed state because the counterclockwise rotation is blocked by the trip lever 120.

In this state, as shown in FIG. 12B, \textcircled{1} when the user manipulates the handle 13, the handle 13 may move the trip shooter 110. At this time, \textcircled{2} the lever holder 150 may start to rotate by the motion core 142, and the motion core 142 may be fixed to the magnet inside the coil assembly 140. Then, \textcircled{3} the trip lever 120 interlocked with the trip shooter 110 by the trip lever spring 120a may move linearly in the same direction as the trip shooter 110. Afterwards, \textcircled{4} the trip lever 120 may be caught and stopped by the stopper 138 formed in the frame 130.

As shown in FIG. 13A, \textcircled{1} only the trip shooter 110 may additionally move even when the handle 13 is operated after the trip lever 120 is stopped. That is, the trip shooter 110 may additionally move and absorb the backlash of the manipulation of the handle 13. In this case, \textcircled{2} only the trip lever spring 120a may be additionally compressed as the trip shooter 110 moves.

Next, referring to FIG. 13B, as the manipulating load of the handle 13 is removed, \textcircled{1} additional compression of the trip shooter 110 may be released, and the trip lever 120 may be also subjected to the load to be returned. However, \textcircled{2} the trip lever catching unit 156 of the lever holder 150 may serve as a latch to stop the trip lever 120. At this time, \textcircled{3} the motion core 142 may be fixed by the binding force of the magnet and may serve to restrict the rotation of the lever holder 150.

In this way, the reset operation of the trip device 100 may be completed.

The following may be the trip operation process. Referring to FIG. 14A, \textcircled{1} when a voltage is applied to the coil assembly 140, an electromagnetic force may act on the motion core 142, such that the binding force by the magnet is reduced.

As shown in FIG. 14B, \textcircled{1} as the electromagnetic force acting on the motion core 142 is greater than the binding force by the magnet, the motion core 142 may move in the direction of the arrow. Also, \textcircled{2} as the lever holder 150 connected to the motion core 142 rotates clockwise, the latch holding the trip lever 120 may be released. In this case, \textcircled{3} as the latch is released, the trip shooter 110 and the trip lever 120 may move forward by the restoring force of the trip shooter spring 110a. Finally, \textcircled{4} the mechanism striking unit 122 of the trip lever 120 may strike the mechanism 14, thereby tripping the circuit breaker.

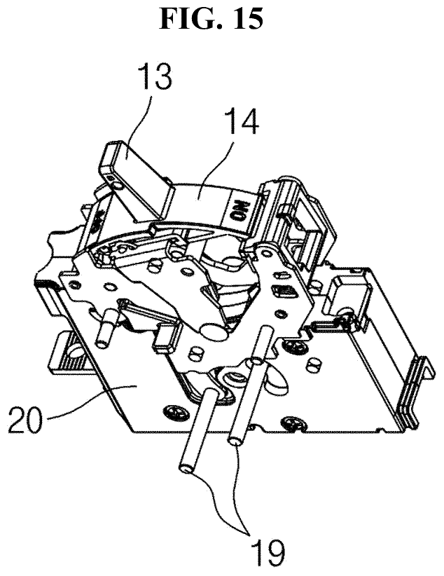

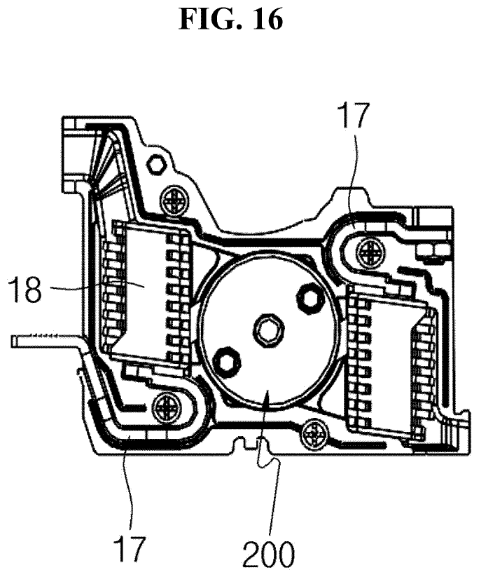

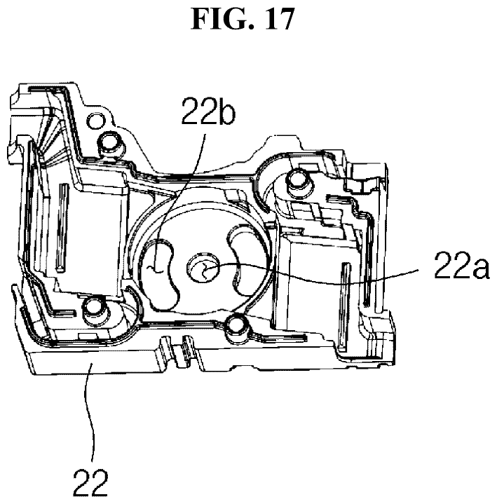

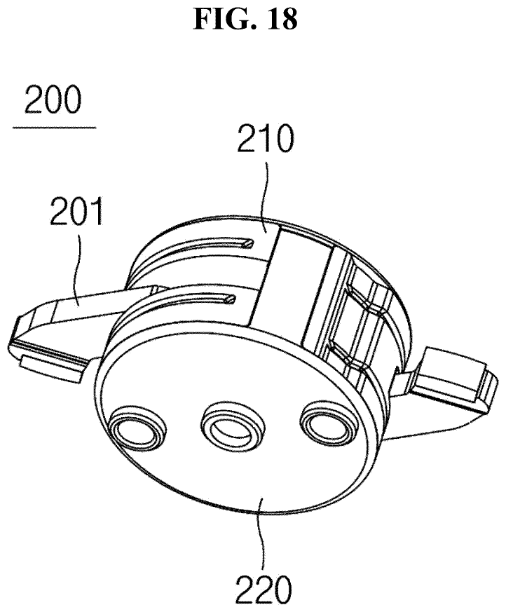

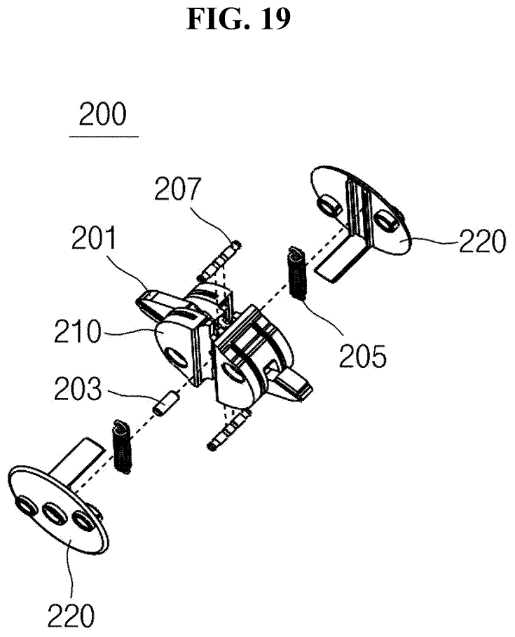

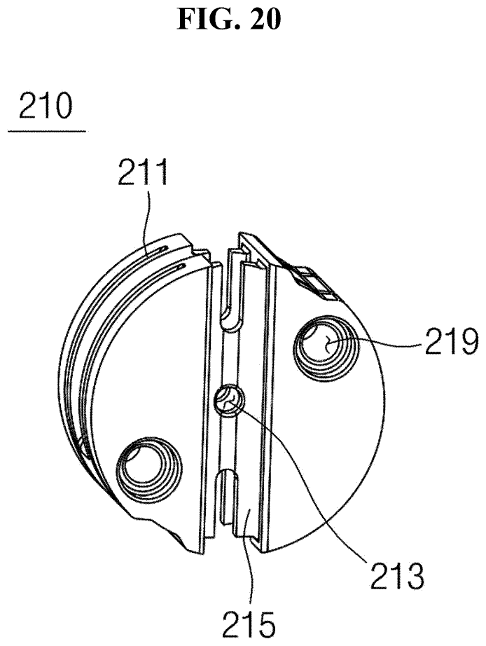

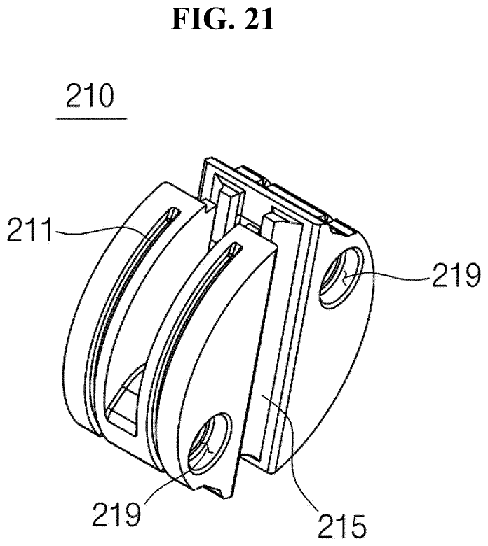

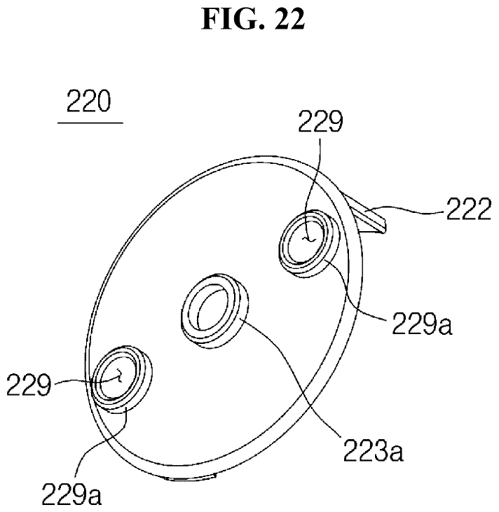

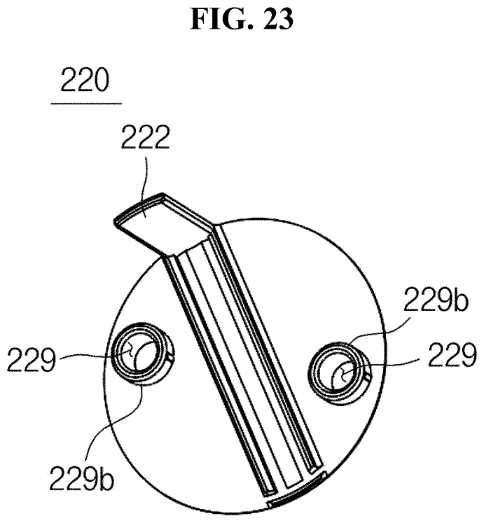

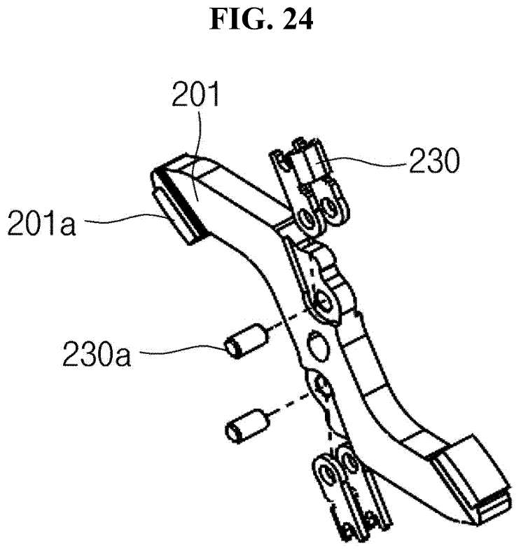

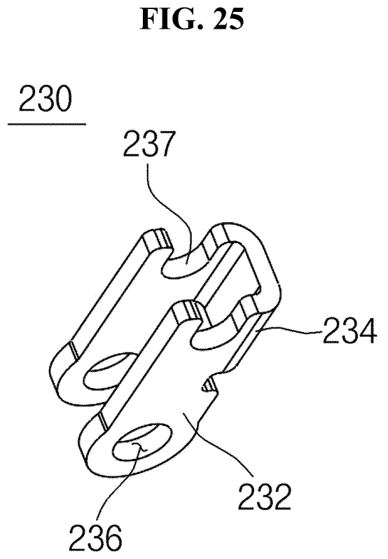

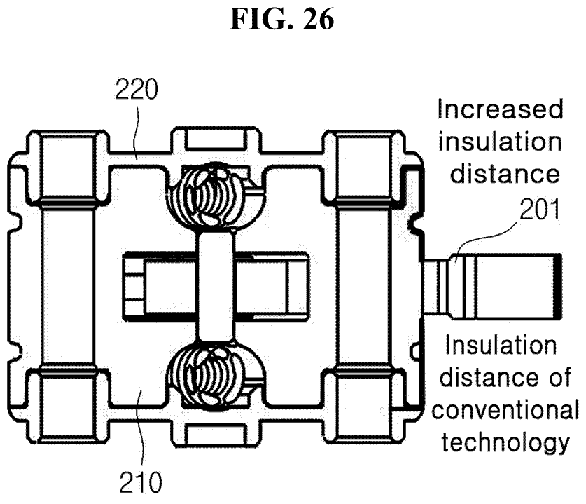

FIG. 15 is a perspective view showing a single-pole breaking unit of a molded case circuit breaker according to an exemplary embodiment of the present disclosure, FIG. 16 is an internal side view showing a single-pole breaking unit of a molded case circuit breaker according to an exemplary embodiment of the present disclosure, and FIG. 17 is a side perspective view showing a contact base of a single-pole breaking unit of a molded case circuit breaker according to an exemplary embodiment of the present disclosure. FIG. 18 is a perspective view showing a crossbar assembly according to an exemplary embodiment of the present disclosure, FIG. 19 is an exploded perspective view showing a crossbar assembly according to an exemplary embodiment of the present disclosure, and FIG. 20 is a perspective view showing a crossbar according to an exemplary embodiment of the present disclosure. FIG. 21 is a perspective view showing a crossbar when viewed from another side according to an exemplary embodiment of the present disclosure, FIG. 22 is a perspective view showing a crossbar cap according to an exemplary embodiment of the present disclosure, and FIG. 23 is a perspective view showing a crossbar cap when viewed from another side according to an exemplary embodiment of the present disclosure. FIG. 24 is an exploded perspective view showing an assembly structure of a movable electrode and a toggle link according to an exemplary embodiment of the present disclosure, FIG. 25 is a perspective view showing an integrated structure of a toggle link according to an exemplary embodiment of the present disclosure, and FIG. 26 is a conceptual diagram showing that a crossbar assembly according to an exemplary embodiment of the present disclosure has an increased insulation distance compared to the conventional one.

Referring to FIGS. 15 to 26, the crossbar assembly 200 according to an exemplary embodiment of the present disclosure may largely include a movable electrode 201 for rotating by the mechanism 14 of the circuit breaker and for performing to open and close a contact point of the circuit breaker, a crossbar 210 for providing a rotation shaft on which the movable electrode 201 can rotate, and a crossbar cap 220 coupled to both sides of the crossbar 210.

First, as shown in FIG. 15, the molded case circuit breaker 1000 according to an exemplary embodiment of the present disclosure may include a single-pole breaking unit 20. The single-pole breaking unit 20 may be provided for each phase in a circuit breaker having a plurality of phases. That is, three single-pole breaking units 20 may be provided in the case of a three-phase molded case circuit breaker 1000 as shown in FIG. 1 of the present exemplary embodiment.

Such a single-pole breaking unit 20 may independently include a terminal unit 15, a movable electrode 201, a fixed electrode 17, an arc extinguishing unit 18, and a crossbar assembly 200. The single-pole breaking unit 20 may include a contact base 22 forming a case, such that each single-pole breaking unit 20 can be physically and electrically separated between phases. In the center of the contact base 22, a crossbar assembly building unit 22a where the crossbar assembly 200 is assembled to be rotatable may be provided.

A rotating pin 19 penetrating and connecting the crossbar assembly 200 provided in each single-pole breaking unit 20 may be provided, and a rotating pin movement hole 22b may be formed in the contact base 22, such that the rotating pin 19 can move along a predetermined radius. By the rotating pin 19 provided in that way, the plurality of crossbar assemblies 200 may rotate in conjunction with each other.

The configuration of the crossbar assembly 200 according to an exemplary embodiment of the present disclosure will be described in more detail as follows.

The crossbar assembly 200 may include a cylindrical crossbar 210. The crossbar 210 may provide a rotation shaft on which the movable electrode 201 may rotate, and as shown in FIG. 19, a crossbar pin 203 serving as the rotation shaft may be assembled to penetrate both the crossbar 210 and the movable electrode 201. The movable electrode 201 may be rotated by the mechanism 14 to open and close the contact point 201a, and the crossbar 210 may provide the rotation shaft for enabling such rotation.

A crossbar spring 205 may be assembled on both sides of the crossbar 210. The crossbar spring 205 may serve to provide a continuous load in a contact state or a contact parting state of the movable electrode 201.

The crossbar spring 205 may be connected to a toggle link 230 by a spring pin 207. One side of the toggle link 230 may be rotatably coupled to the movable electrode 201 through a toggle link pin 230a and the other side may be rotatably connected to the crossbar spring 205 through a spring pin 207.

The toggle link 230 configured in this manner may serve to change the load direction transmitted to the movable electrode 201 according to the contact state or the contact parting state of the movable electrode 201. That is, the toggle link 230 may change the load direction according to the rotation position of the movable electrode 201. Herein, the spring pin 207 may transmit the elastic force of the crossbar spring 205 to the toggle link 230, and the toggle link pin 230a may transmit this force to the movable electrode 201.

Specifically, the toggle link 230 may transmit a load to increase the contact load through the elastic force of the crossbar spring 205 in a state where the movable electrode 201 is in contact with the fixed electrode 17. Also, in order to perform interruption, in a contact parting state of the movable electrode 201, the load direction on which the toggle link 230 acts may be changed to transmit the load in the contact parting direction, that is, in the direction away from the contact.

Meanwhile, an insulating groove 211 may be formed along the circumferential surface of the crossbar 210. As shown in FIGS. 20 and 21, the insulating groove 211 may be formed as a recessed portion on the circumferential surface of the crossbar 210 in order to increase the insulation distance. In the present exemplary embodiment, four grooves may formed, two on one circumferential surface and two on the other circumferential surface, but the present disclosure may not be limited thereto. The length, width, and depth of the insulating groove 211 may be variously modified. The insulation performance may be improved by increasing the insulation distance through the insulating groove 211.

A crossbar pin penetrating hole 213 through which the crossbar pin 203 penetrates may be formed at the center of the crossbar 210. A crossbar penetrating hole 219 through which the rotating pin 19 penetrates may be formed in a direction symmetrical to each other with respect to the crossbar pin penetrating hole 213. Also, a spring mounting unit 215 where the crossbar spring 205 is mounted may be formed along the diametric direction of the crossbar 210.

A crossbar cap 220 may be coupled to both sides of the crossbar 210. The crossbar cap 220 may be manufactured from a thermoplastic material resistant to friction and insulation, thereby improving insulation performance and minimizing dust caused by friction. Also, the crossbar cap 220 may be assembled to cover both sides of the crossbar 210 and may serve to protect the crossbar spring 205.

Herein, the crossbar cap 220 may include a cover unit 222 extending from one side thereof and configured to cover the open portion of the crossbar 210 to prevent gas and molten material from flowing into the inside.

The cover unit 222 may serve to increase insulation performance by covering the exposed portions of the toggle link 230 and the crossbar spring 205 and to prevent contamination caused by the ingress of gas and molten material.

As shown in FIG. 19, the cover unit 222 may be applied, such that one side of the crossbar cap 220 is formed to extend from the upper portion and the other side of the crossbar cap 220 is formed to extend from the lower portion, respectively, to cover the open portions at the upper and lower portions of the crossbar 210.

The crossbar cap 220 may include at least one rotating pin penetrating hole 229 through which the rotating pin 19 penetrates. In the present exemplary embodiment, two may be formed in a direction symmetrical to each other with respect to the center of the crossbar cap 220.

An inner extending unit 229b and an outer extending unit 229a may be formed around the rotating pin penetrating hole 229. The inner extending unit 229b may be formed to extend from the periphery of the rotating pin penetrating hole 229 toward the crossbar 210, and the outer extending unit 229a may be formed to extend from the periphery of the rotating pin penetrating hole 229 toward an outer direction, that is, a direction opposite to where the inner extending unit 229b is extended. The inner extending unit 229b and the outer extending unit 229a may increase an insulation distance between phases through the rotating pin 19.

The crossbar cap 220 may include an assembly extending unit 223a formed to extend from the center so as to be rotatably coupled to the contact base 22 of the single-pole breaking unit 20. The assembly extending unit 223a may serve to maintain the gap between the crossbar assembly 200 and the contact base 22 without contacting each other. At this time, it is preferable to form the height of the assembly extending unit 223a so that the gap between the circumferential surface of the crossbar assembly 200 and the contact base 22 is greater than 0.33 mm.

As shown in FIG. 26, the crossbar assembly 200 configured in this manner may secure insulation stability by increasing the insulation distance compared to the conventional one.

Meanwhile, the toggle links 230 disposed at positions facing each other may be connected by a link connecting unit 234 to form an integrated body.

Conventionally, the toggle links 230 may be formed as a pair of the toggle links 230 separately disposed to face each other, and in this case, may have a structure where a pair of toggle links 230 are aligned and then riveted to the pin, so there is a problem of resulting in abnormal operations because the spring pin 207 is twisted and interfered with the crossbar 210 when riveted in a state where the positions of both toggle links 230 are twisted in the manufacturing process.

However, when the toggle link 230 is formed as an integrated body like the present exemplary embodiment, the aforementioned defects may be prevented, operational reliability can be secured, and productivity can be improved by reducing the assembly number of riveting processes.

As such, the toggle link 230 according to an exemplary embodiment of the present disclosure may be formed as an integrated body including a toggle link main body 232 and a link connecting unit 234. Besides, the toggle link 230 may include a toggle link pin assembling unit 236 into which the toggle link pin 230a is inserted and a spring pin assembling unit 237 coupled to the spring pin 207.

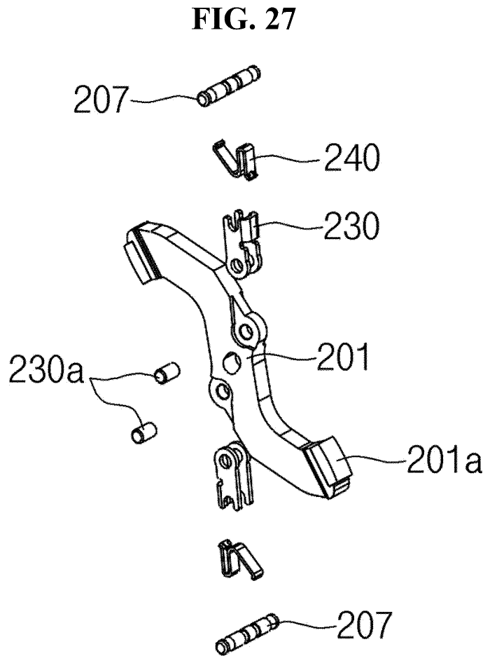

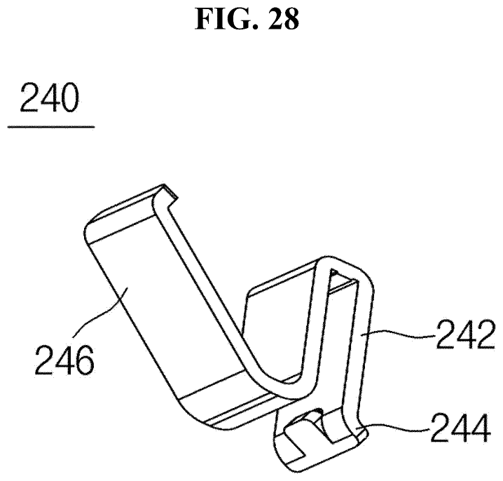

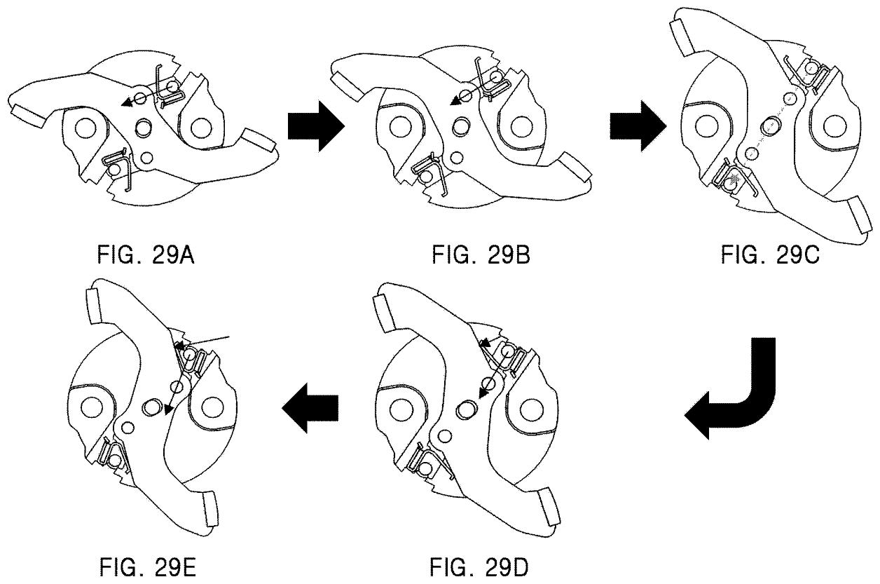

FIG. 27 is a perspective view showing a case where a toggle link spring is applied to a movable electrode and a toggle link according to an exemplary embodiment of the present disclosure, FIG. 28 is a perspective view showing a toggle link spring according to an exemplary embodiment of the present disclosure, and FIGS. 29A, 29B, 29C, 29D, and 29E are a side view sequentially showing a contact parting process of a movable electrode in a crossbar assembly according to an exemplary embodiment of the present disclosure.

Referring to FIGS. 27 to 29, the crossbar assembly 200 according to an exemplary embodiment of the present disclosure may further include a toggle link spring 240 having one side coupled to the toggle link 230 and the other side in contact with the movable electrode 201 for providing a return load to the movable electrode 201 in a contact parting state.

Specifically, as shown in FIGS. 26 and 27, the toggle link spring 240 may include a toggle link coupling unit 242 inserted into and coupled to the link connecting unit 234. The toggle link 230 and the toggle link spring 240 may be coupled by inserting the link connecting unit 234 of the toggle link 230 into the toggle link coupling unit 242.

Also, there is provided a spring separation preventing unit 244 to be bent and extended outwardly from one side end of the toggle link coupling unit 242. The spring separation preventing unit 244 may serve to prevent the toggle link 230 and the toggle link spring 240 from being detached in the coupled state.

The toggle link spring 240 may include a contact unit 246 extending by a predetermined length in a curved state from the other side end of the toggle link coupling unit 242. The contact unit 246 may serve to transmit a return load by contacting the movable electrode 201 in a contact parting state.

FIGS. 29A, 29B, 29C, 29D, and 29E are views showing an operation process of the toggle link spring 240. FIG. 29A is a view showing a state in which the toggle link spring 240 is first assembled, and FIG. 29B is a view showing a state in which the movable electrode 201 is inserted to contact the contact point 201a. FIG. 29C is a view showing a state where the movable electrode 201 passes a dead point where the toggle link 230 and the crossbar spring 205 are in a straight line as the contact parting starts, and FIG. 29D is a view showing a moment when the movable electrode 201 further rotates and comes in contact with the toggle link spring 240. Also, FIG. 29E is a view showing a state where the movable electrode 201 does fully contact parting such that the toggle link spring 240 is deformed and a return load is applied.

In this way, when a current-limiting operation of the movable electrode 201 occurs because of a fault current and the movable electrode 201 passes the dead point to come into contact with the toggle link spring 240, the load of the toggle link spring 240 may act as the return load of the movable electrode 201.

At this time, the elastic coefficient may be adjusted by the shape, thickness, and the like of the toggle link spring 240, and the return load after the dead point may be intentionally adjusted according to the load size. Therefore, it is possible to change the position of the dead point for improving the short-circuit performance, the contact parting speed may be improved according to the movement of the dead point, and the return safety distance for impact may be increased, such that the effect of preventing re-ignition in the event of a short circuit may be also increased.

According to the exemplary embodiments of the present disclosure described so far, the exemplary embodiments may effectively absorb the backlash generated in the event of the handle manipulation to prevent malfunction of trip operation, optimize the design of parts inside the trip device, and house the PCB module of the coil assembly inside the trip device by replacing the rotational operation and the coil spring structure of the existing trip device with a linear motion and a compression spring application structure and minimizing the volume required for implementing operations.

Also, it is possible to provide a miniaturized design applicable to circuit breakers of various structures by reducing the size of the trip device, to increase productivity and maintenance efficiency at the same time by improving the assembly of the trip device, to improve the operation speed so that the arc can quickly be extinguished in the event of a short circuit while improving the insulation performance and the assembly of the toggle-type current-limiting device, and to ensure reliability even in high-voltage environments by optimizing the insulation structure of the crossbar and the crossbar cap.

In addition, it is possible to solve the torsion problem of the toggle link applied to the crossbar assembly, to eliminate instability generated during assembly through an integrated structure, and to shorten the arc extinction time and increase the success rate of circuit interruption in the event of a short circuit by optimizing the contact parting distance and speed.

Furthermore, it is possible to enhance the stability and reliability of the return operation after a short circuit event by improving the return structure of the toggle-type current-limiting mechanism, and to prevent re-ignition caused by external impacts by allowing the movable electrode to stably be returned to the initial position, by introducing a spring structure for carefully adjusting the return load and by minimizing excessive load generated during the return.

The present disclosure has been described above with reference to an exemplary embodiment, but those skilled in the art will be able to implement various modifications and changes to the present disclosure within the scope not departing from the spirit and scope of the present disclosure described in the claims described below. Therefore, when the modified exemplary embodiments basically include components of the claims of the present disclosure, all should be considered to be included in the technical scope of the present disclosure.

1. A circuit breaker trip device, the device comprising:
a trip shooter for moving by a reset operation of a circuit breaker handle; and
a trip lever interlocked with the trip shooter for moving to a reset position,
wherein the trip shooter additionally moves by a predetermined length even after the trip lever stops at the reset position.

2. The device of claim 1, further comprising:
a frame forming an outer shape of the trip device and to which the trip lever is slidably coupled.

3. The device of claim 2, wherein the trip shooter is slidably coupled between the trip lever and the frame.

4. The device of claim 3, further comprising:
a trip shooter spring for connecting the frame and the trip shooter; and
a trip lever spring for connecting the trip shooter and the trip lever.

5. The device of claim 2, further comprising:
a coil assembly provided inside the frame for generating an electromagnetic force in response to an external voltage; and
a motion core configured to be fixed by a magnet provided inside the coil assembly or to move away from the magnet by the electromagnetic force.

6. The device of claim 5, further comprising:
a lever holder, one side of which is connected to the motion core and rotates according to a movement of the motion core.

7. The device of claim 6, wherein the lever holder serves as a latch for restricting the trip lever to be fixed at the reset position or releasing the same.

8. The device of claim 6, further comprising:
a lever holder pin forming a rotation shaft of the lever holder.

9. The device of claim 8, further comprising:
a frame cover configured to be coupled to one side of the frame.

10. The device of claim 9, further comprising:
a lever holder pin separation preventing unit formed to extend by a predetermined length from the frame cover toward the frame for preventing the lever holder pin from being detached.

11. The device of claim 9, further comprising:
a trip lever separation preventing unit formed to extend by a predetermined length from the frame cover toward the frame for preventing the trip lever from being detached.

12. The device of claim 2, wherein the trip lever comprises:
at least one guiding groove unit for preventing a detachment of the trip lever assembled to the frame and for forming a path where the trip lever moves.

13. The device of claim 12, wherein the frame comprises:
at least one stopper interlocked with the guiding groove unit for guiding a movement of the trip lever and for stopping the trip lever from moving further after moving to the reset position.

14. The device of claim 5, further comprising:
a printed circuit board (PCB) unit electrically connected to the coil assembly for receiving an external voltage signal and supplying a voltage to the coil assembly,
wherein the PCB unit is housed inside the frame.

15. The device of claim 1, wherein the trip device is a shunt trip (SHT) or an under voltage trip (UVT).

16. A molded case circuit breaker, the breaker comprising:
a terminal unit for inputting and outputting current;
a fixed electrode electrically connected to the terminal unit;
a movable electrode electrically connected to or disconnected from the fixed electrode in order to interrupt or establish a current flow;
a mechanism for opening and closing an electrical connection to the fixed electrode by moving the movable electrode;
a handle connected to the mechanism to be manually operable; and
a trip device for operating the mechanism when a voltage drops or according to an external voltage signal,
wherein the trip device comprises:
a trip shooter for linearly moving in response to a reset operation of the handle; and
a trip lever interlocked with the trip shooter for linearly moving to a reset position.

17. The breaker of claim 16, wherein the trip shooter additionally moves by a predetermined length even after the trip lever stops at the reset position.

18. The breaker of claim 17, wherein the trip device further comprises a frame forming an outer shape of the trip device and to which the trip lever is slidably coupled and
the trip shooter is slidably coupled between the trip lever and the frame.

19. The breaker of claim 18, wherein the trip device further comprises:
a coil assembly provided inside the frame for generating an electromagnetic force in response to an external voltage;
a motion core configured to be fixed by a magnet provided inside the coil assembly or to move away from the magnet by the electromagnetic force; and
a lever holder, one side of which is connected to the motion core and rotates according to a movement of the motion core.

20. The breaker of claim 19, wherein the trip device further comprises:
a printed circuit board (PCB) unit electrically connected to the coil assembly for receiving an external voltage signal and supplying a voltage to the coil assembly,
wherein the PCB unit is housed inside the frame.
